(19) United States
(12) Patent Application Publication
(10) Pub. No.: US 2013/0050946 A1
(43) Pub. Date: Feb. 28, 2013

(54) FASTENING MECHANISM FOR FIXING RADIATOR

(71) Applicants: XIAO-FENG MA, Shenzhen City (CN); LIANG TAN, Shenzhen City (CN)

(72) Inventors: XIAO-FENG MA, Shenzhen City (CN); LIANG TAN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (TW)

(21) Appl. No.: 13/433,638

(22) Filed: Mar. 29, 2012

(30) Foreign Application Priority Data
Aug. 31, 2011 (CN) 201110254652.4

(51) Int. Cl. H05K 7/20

(52) U.S. Cl. 361/709

(57) ABSTRACT

A fastening mechanism for fixing a radiator having a plurality of heat sinks to a circuit board includes two fixing rods fixed on the circuit board, a connecting member positioned between the heat sinks; and two fastening arms respectively connecting the connecting member to the fixing rods. An electronic device using the fastening mechanism is also provided.

### BACKGROUND

1. Technical Field

The present disclosure generally relates to fastening mechanisms, and particularly to a fastening mechanism for fixing a radiator.

2. Description of the Related Art

Electrical components, such as a CPU of a computer, generate a great deal of heat. Excessive heat can affect the performance of the CPU or damage the CPU. A radiator is usually fixed on the CPU via a fastening mechanism to cool the CPU. However, the current fastening mechanism has a complex structure and is difficult to operate.

Therefore, there is room for improvement within the art.

### BRIEF DESCRIPTION OF THE DRAWING

The components in the drawings are not necessarily drawn to scale, the emphasis instead placed upon clearly illustrating the principles of the present disclosure. Moreover, in the drawings, like reference numerals designate corresponding parts throughout the several views.

FIG. 1 is an exploded, isometric view of an embodiment of an electronic device including a circuit board, a chip, a radiator, and a fastening mechanism.

FIG. 2 is a side view of the radiator of FIG. 1.

FIG. 3 is an assembled, isometric view of the electronic device of FIG. 1.

FIG. 4 is similar to FIG. 3, with the radiator fixed to the circuit board by the fastening mechanism.

FIG. 5 is a side view of the electronic device of FIG. 4.

### DETAILED DESCRIPTION

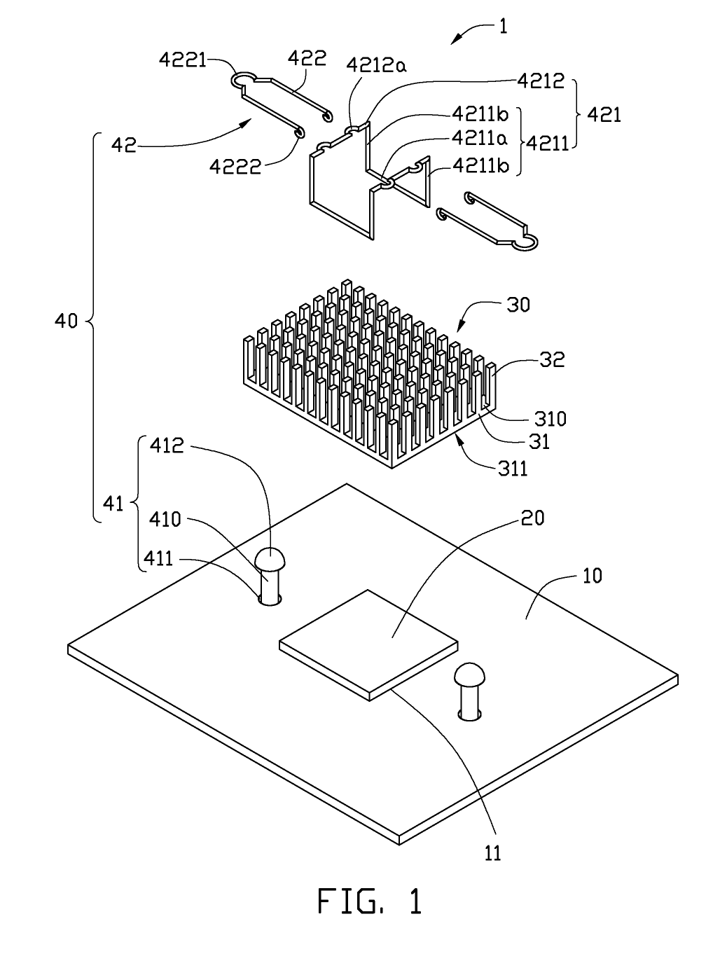

Referring to FIG. 1, an embodiment of an electronic device 1 includes a circuit board 10, a chip 20 positioned on the circuit board 10, a radiator 30 for cooling the chip 20, and a fastening mechanism 40 fixing the radiator 30 to the circuit board 10. The circuit board 10 includes a chip base 11 for positioning the chip 20. In the illustrated embodiment, the circuit board 10 is a motherboard, and the chip 20 is a CPU.

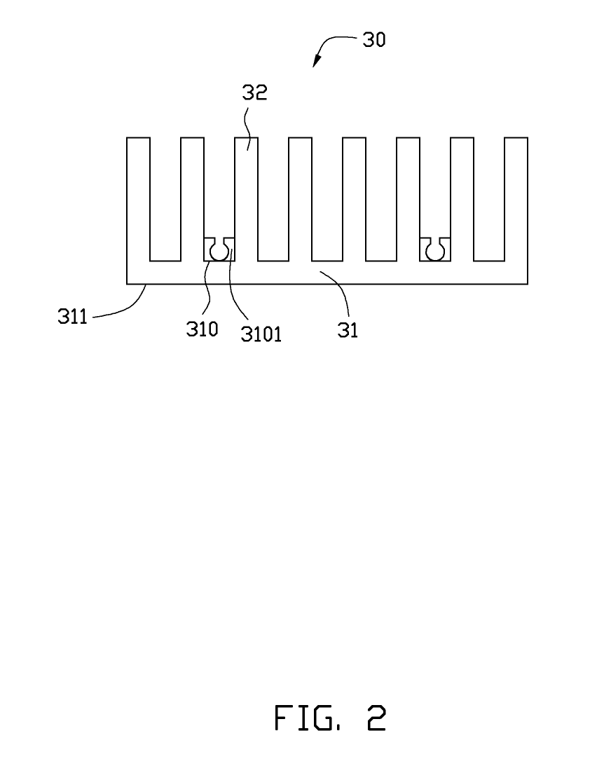

Referring to FIG. 2, the radiator 30 includes a conducting base 31 and a plurality of heat sinks 32 formed on the conducting base 31. The conducting base 31 includes a top surface 310 and a bottom surface 311 opposite to the top surface 310. The conducting base 31 is positioned on the chip 20, with the bottom surface 311 facing the chip 20. The heat sinks 32 are formed on the top surface 310. The top surface 310 further forms a plurality of positioning members 3101 arranged between the heat sinks 32 and in two parallel rows. In the illustrated embodiment, the chip 20 and the conducting base 31 are rectangular-shaped, and the heat sinks 32 are arranged in a matrix.

The fastening mechanism 40 includes two fixing rods 41 positioned near opposite sides of the conducting base 31, and a fastening assembly 42 positioned between the heat sinks 32. Each fixing rod 41 includes a main body 410, a fixing end 411, and a restricting end 412. The fixing end 411 and the restricting end 412 are positioned on opposite ends of the main body 410. The fixing end 411 is fixed to the circuit board 10.

The fastening assembly 42 includes a connecting member 421 and two fastening arms 422 connected to the connecting member 421. The connecting member 421 includes two positioning arms 4211 substantially parallel to each other, and two connecting poles 4212 connecting the positioning arms 4211. Each positioning arm 4211 is substantially U-shaped, and includes a first section 4211a and two second sections 4211b extending substantially perpendicularly from opposite ends of the first section 4211a. A length of the second sections 4211b is larger than a height of the heat sinks 32 relative to the circuit board 10. Each connecting pole 4212 is connected to the second sections 4211b of the positioning arms 4211, and is substantially perpendicular to the positioning arm 4211. Two arc-shaped receiving portions 4212a are formed on each positioning arm 4211. In an alternative embodiment, the positioning arm 4211 may have three or more receiving portions 4212a.

Each fastening arm 422 is substantially U-shaped, and forms a connecting portion 4221 at a first end, and two hook portions 4222 at a second end opposite to the first end. In the illustrated embodiment, the connecting portion 4221 is arc-shaped, and restricting end 412 is hemispherical. A radius of the connecting portion 4221 is less than that of the restricting end 412 and greater than a radius of the main body 410, so that the connecting portion 4221 can sleeve on the main body 410 and resist the restricting end 412. The hook portions 4222 engage with the receiving portions 4212a of the connecting member 421, thereby rotatably connecting the fastening arm 422 to the connecting member 421. In alternative embodiments, the hook portions 4222 can be fixed to the receiving portions 4212a, and the fastening arm 422 and the connecting member 421 can be integrally formed.

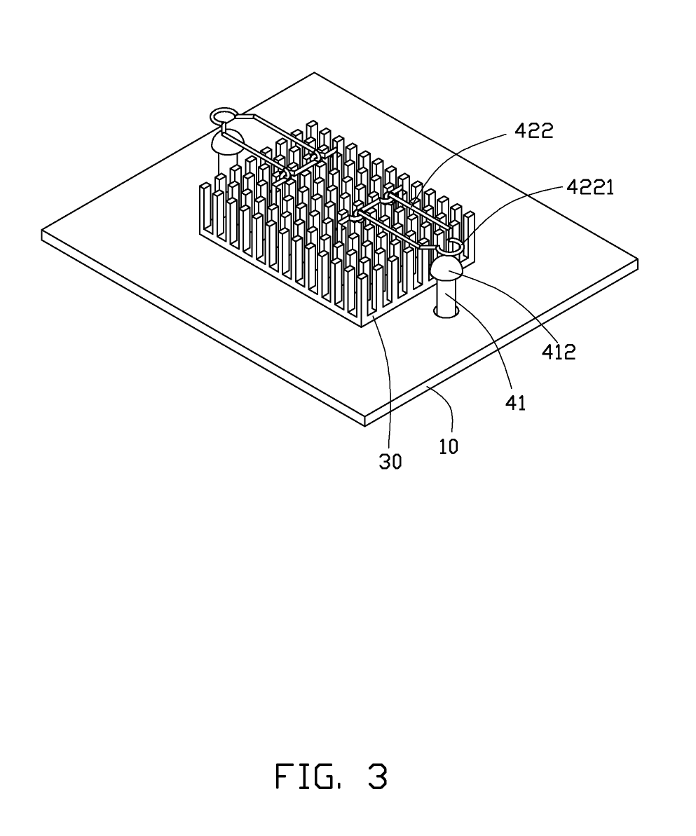

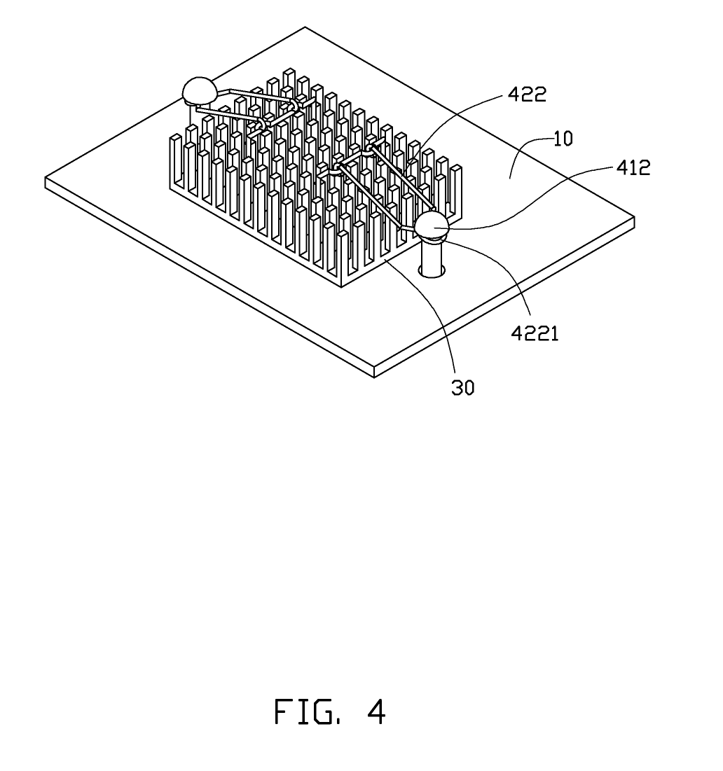

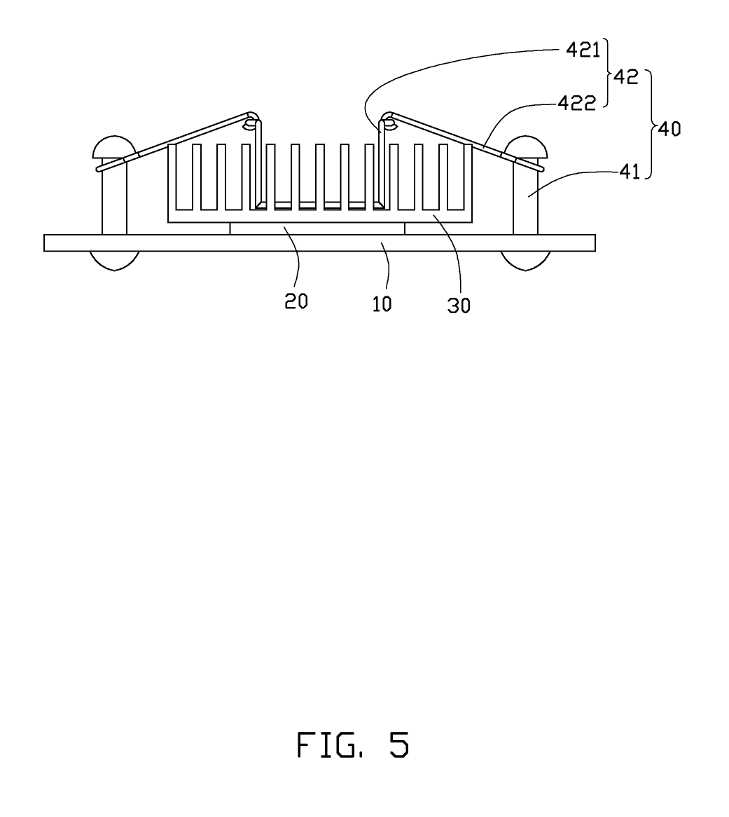

Referring to FIG. 3 through 5, in assembling the radiator 30 to the circuit board 10, the first sections 4211a of the connecting member 421 engage with the positioning members 3101, thereby fixing the connecting member 421 on the radiator 30. The hook portions 4222 of the fastening arms 422 engage with the receiving portions 4212a of the connecting member 421. The radiator 30 is positioned on the chip 20, and then the fastening arms 422 are pushed downwards to make the connecting portion 4221 sleeve on the fixing rods 41. After that, the radiator 30 is fixed to the circuit board 10. Therefore, the fastening mechanism 40 has a simple structure, and is easily operated.

While the present disclosure has been described with reference to particular embodiments, the description is illustrative of the disclosure and is not to be construed as limiting the disclosure. Therefore, various modifications can be made to the embodiments by those of ordinary skill in the art without departing from the true spirit and scope of the disclosure, as defined by the appended claims.

What is claimed is:

1. A fastening mechanism for fixing a radiator having a plurality of heat sinks to a circuit board comprising:
two fixing rods fixed on the circuit board;
a connecting member positioned between the heat sinks; and
two fastening arms respectively connecting the connecting member to the fixing rods, thereby fixing the radiator to the circuit board.

2. The fastening mechanism of claim 1, wherein the connecting member comprises two positioning arms substantially parallel to each other and two connecting poles connecting the positioning arms.

3. The fastening mechanism of claim 2, wherein each of the positioning arms is substantially U-shaped, and comprises a first section and two second sections extending substantially perpendicularly from opposite ends of the first section.

4. The fastening mechanism of claim 3, wherein a length of each of the second sections is larger than that a height of the heat sinks relative to the circuit board.

5. The fastening mechanism of claim 1, wherein each of the fixing rods comprises a main body, a fixing end, and a restricting end; the fixing end and the restricting end are positioned on opposite ends of the main body, and the fixing end is fixed to the circuit board.

6. The fastening mechanism of claim 5, wherein each of the fastening arms forms a connecting portion at a first end, and the connecting portion sleeves on the main body of the fixing rod.

7. The fastening mechanism of claim 6, wherein each of the fastening arms further forms two hook portions at a second end opposite to the first end, and the hook portions engage with the connecting member.

8. A n electronic device, comprising:
a circuit board;
a chip positioned on the circuit board,
a radiator comprising a conducting base and a plurality of heat sinks formed on the conducting base, and
a fastening mechanism fixing the radiator to the circuit board, the fastening mechanism comprising:
two fixing rods fixed on the circuit board;
a connecting member positioned between the heat sinks; and
two fastening arms connecting the connecting member to the fixing rods, thereby fixing the radiator to the circuit board.

9. The electronic device of claim 8, wherein the connecting member comprises two positioning arms substantially parallel to each other and two connecting poles connecting the positioning arms.

10. The electronic device of claim 9, wherein each of the positioning arms is substantially U-shaped, and comprises a first section and two second sections extending substantially perpendicularly from opposite ends of the first section.

11. The electronic device of claim 10, wherein a length of the second sections is larger than a height of the heat sinks relative to the circuit board.

12. The electronic device of claim 8, wherein each of the fixing rods comprises a main body, a fixing end, and a restricting end; the fixing end and the restricting end are positioned on opposite ends of the main body, and the fixing end is fixed to the circuit board.

13. The electronic device of claim 12, wherein each of the fastening arms forms a connecting portion at a first end, and the connecting portion sleeves on the main body of the fixing rod.

14. The electronic device of claim 13, wherein each of the fastening arm further forms two hook portions at a second end opposite to the first end, and the hook portions engage with the connecting member.

15. The electronic device of claim 1, wherein the radiator further comprises a plurality of positioning members arranged between the heat sinks; the connecting member engages with the plurality of positioning members.

16. The electronic device of claim 15, wherein the plurality of positioning members are arranged in two parallel rows.
